(19) United States
(12) Patent Application Publication
(10) Pub. No.: US 2026/0317946 A1
(43) Pub. Date: Oct. 15, 2026

(54) ION IRRADIATION OF FUNCTIONAL WURTZITES

(71) Applicants: UT-Battelle, LLC, Oak Ridge, TN (US); THE PENN STATE RESEARCH FOUNDATION, State College, PA (US)

(72) Inventors: Kyle P. Kelley, Knoxville, TN (US); Steven Randolph, Oak Ridge, TN (US); Jon-Paul Maria, State College, PA (US); Bogdan Dryzhakov, Oak Ridge, TN (US)

(21) Appl. No.: 19/644,100

(22) Filed: Apr. 10, 2026

Related U.S. Application Data
(60) Provisional application No. 63/787,533, filed on Apr. 11, 2025.

(51) Int. Cl. C30B 25/06; C30B 25/18; C30B 29/40

(52) U.S. Cl. CPC C30B 25/06; C30B 25/18; C30B 29/403

(57) ABSTRACT

A method of inducing kinetic transformations in the defect chemistry of a wurtzite material includes: providing a substrate comprised of a wurtzite material having a crystalline structure in an initial state and defining a ferroelectric coercive field; and irradiating the substrate with energetic particles to stabilize a defect chemistry in the crystalline structure of the wurtzite material, such that the irradiated substrate has a lower switching energy barrier than the initial state of the crystalline structure of the wurtzite material thereby reducing the coercive field of the substrate. The energetic particles may be ions with an energy in a range of from 0.1 keV to 3000 keV. The energetic particles may be inert ions, reactive ions, or metal ions. The wurtzite material may be a wurtzite nitride material or a mixed wurtzite nitride material. The coercive field may be reduced in an amount proportional to an amount of the irradiation.

### CROSS-REFERENCE TO RELATED APPLICATIONS

This application claims the benefit of U.S. Provisional Application No. 63/787,533, filed Apr. 11, 2025, the disclosure of which is incorporated by reference in its entirety.

### STATEMENT REGARDING FEDERALLY SPONSORED RESEARCH AND DEVELOPMENT

This invention was made with government support under Contract No. DE-AC05-00OR22725 awarded by the U.S. Department of Energy. The government has certain rights in the invention.

### FIELD OF THE INVENTION

The present invention relates to wurtzite materials, and more particularly to a method of inducing kinetic transformations in the defect chemistry of wurtzite materials to activate ferroelectric properties.

### BACKGROUND OF THE INVENTION

Recently, wurtzite materials such as aluminum nitride (AIN) have been explored for their ferroelectricity. Wurtzite ferroelectrics exhibit exceptional spontaneous polarization at nanoscale thicknesses, a wide bandgap, and thermal stability. Wurtzite ferroelectrics open up a plethora of applications, with back-end-of-line compatibility, spanning from ultrasonics to ferroelectric random access memory. Yet, the electric field strength required to switch the ferroelectric polarization state in wurtzite ferroelectrics is as high as 6 MV/cm. Reducing the coercive field (i.e., the energy necessary for switching the polarization state) in wurtzite ferroelectrics remains a considerable challenge despite numerous endeavors by researchers in the field. Currently, the achieved reductions are typically through methods of strain manipulation and introduction of various cations. However, a need continues to exist for methods of reducing the coercive field of wurtzite materials.

### SUMMARY OF THE INVENTION

A method of inducing kinetic transformations in the defect chemistry of a wurtzite material is provided. The method includes providing a substrate comprised of a wurtzite material having a crystalline structure in an initial state and defining a ferroelectric coercive field. The method further includes irradiating the substrate with energetic particles to stabilize a defect chemistry in the crystalline structure of the wurtzite material, such that the irradiated substrate has a lower switching energy barrier than the initial state of the crystalline structure of the wurtzite material and whereby the coercive field of the substrate is reduced.

In specific embodiments, the energetic particles are ions with an energy that is in a range of from 0.1 keV to 3000 keV.

In specific embodiments, the energetic particles are helium ions.

In particular embodiments, the energetic particles have an energy that is equal to or less than approximately 30 keV.

In specific embodiments, the energetic particles are inert ions.

In specific embodiments, the energetic particles are reactive ions.

In specific embodiments, the energetic particles are metal ions.

In specific embodiments, the wurtzite material is a wurtzite nitride material or a mixed wurtzite nitride material.

In particular embodiments, the wurtzite material is aluminum nitride, gallium nitride, indium nitride, boron-substituted aluminum nitride, scandium-substituted aluminum nitride, aluminum gallium nitride, or indium gallium aluminum nitride.

In specific embodiments, the coercive field is reduced in an amount proportional to an amount of the irradiation.

In particular embodiments, the coercive field is reduced in a range of from greater than 0 to up to 40%.

In specific embodiments, the irradiation is performed by energetic particle bombardment that is one of focused-beam ion irradiation, broad-beam ion irradiation, and plasma-based ion bombardment.

In other embodiments, a method of inducing kinetic transformations in the defect chemistry of a wurtzite material by energetic particle irradiation includes providing a substrate comprised of a wurtzite material having a spontaneous polarization and a ferroelectric coercive field. The method further includes defining a pattern area on the substrate. The method further includes ionizing a source gas to produce positively-charged ions. The method further includes accelerating the positively-charged ions by applying an acceleration voltage and electrostatically focusing the accelerated ions into a nanometer-scale beam. The method further includes scanning the beam over the pattern area of the substrate, such that the beam induces a modification of crystalline microstructure and/or defect chemistry of the wurtzite material, thereby reducing the coercive field of the substrate.

In specific embodiments, the accelerated ions have an energy that is in a range of from 0.1 keV to 3000 keV.

In specific embodiments, the source gas comprises at least one of helium gas, oxygen gas, nitrogen gas, or an inert gas.

In specific embodiments, the wurtzite material is a wurtzite nitride material or a mixed wurtzite nitride material.

In yet other embodiments, a method of inducing kinetic transformations in the defect chemistry of a wurtzite material includes providing a substrate comprised of a wurtzite material having a spontaneous polarization and a ferroelectric coercive field. The method further includes defining a pattern area on the substrate. The method further includes providing a source of energetic particles. The method further includes irradiating the pattern area of the substrate with the energetic particles, such that the energetic particles induce a modification of crystalline microstructure and/or defect chemistry of the wurtzite material, thereby reducing the coercive field of the substrate.

In specific embodiments, the energetic particles have an energy that is in a range of from 0.5 keV to 3000 keV.

In specific embodiments, the energetic particles are one of inert gas ions, non-inert gas ions, and metallic ions.

In specific embodiments, the energetic particles are one of positively-charged ions, negatively-charged ions, or charge neutral particles.

In specific embodiments, the wurtzite material is a wurtzite nitride material or a mixed wurtzite nitride material.

These and other features of the invention will be more fully understood and appreciated by reference to the description of the embodiments and the drawings.

### BRIEF DESCRIPTION OF THE DRAWINGS

FIG. 1 is a schematic view of a method of inducing kinetic transformations in the defect chemistry of a wurtzite material in accordance with embodiments of the disclosure;

FIG. 2 is a schematic view of simulation snapshots for irradiation, equilibration, and polarization switching of a wurtzite material;

FIG. 3A is a graph of hysteresis loops of pristine AIN wurtzite material and helium ion-irradiated AIN in accordance with embodiments of the disclosure;

FIG. 3B is a graph of hysteresis loops of pristine Al_{0.92}B_{0.08}N wurtzite material and helium ion-irradiated Al_{0.92}B_{0.08}N in accordance with embodiments of the disclosure;

FIG. 4 is a schematic view of a method of helium ion irradiation of Al_{0.92}B_{0.08}N ferroelectric capacitors in accordance with embodiments of the disclosure;

FIG. 5 is a graph of piezoelectric response as a function of AC voltage (0.95 Hz) for pristine and irradiated samples;

FIG. 6 is a graph of fitted coefficients of variable AC voltage response curves corresponding to the effective piezoelectric coefficient (d_{33,eff}) and non-linear coefficient (α);

FIG. 7 is a graph of hysteresis loops (First-Order Reversal Curves, FORC) for pristine and irradiated samples at various ion doses; and

FIG. 8 is a graph of coercive voltage (as an average of the absolute values of the positive and negative coercive voltages) as a function of helium ion irradiation dose.

### DETAILED DESCRIPTION OF THE CURRENT EMBODIMENTS

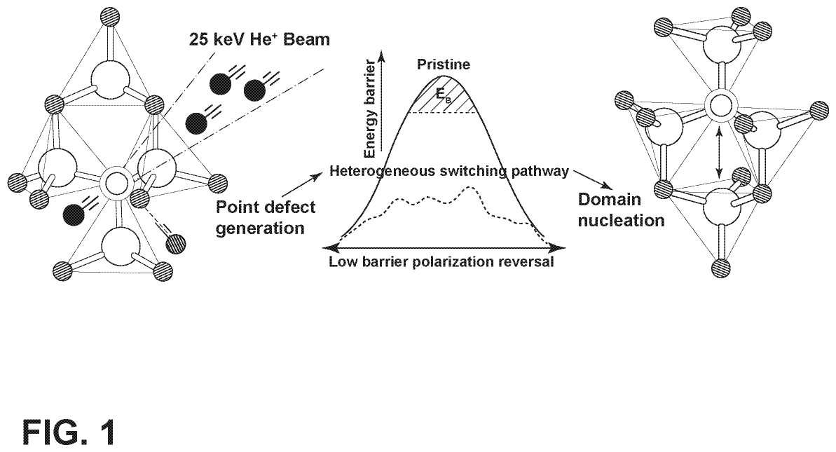

As discussed herein, the current embodiments relate to a method of inducing kinetic transformations in the defect chemistry of a wurtzite material. As generally illustrated in FIG. 1, the method includes irradiating a wurtzite material with energetic particles to stabilize a defect chemistry in the wurtzite material. Each step of the method is discussed below.

In various embodiments, the method first includes providing a substrate that is comprised of a wurtzite material. The wurtzite material may form a layer of the substrate, a portion or portions of the substrate, or may constitute the entire substrate. The wurtzite material has a crystalline structure in an initial state and defines a ferroelectric coercive field and exhibits spontaneous polarization. The coercive field may also be referred to as electric coercivity or switching energy barrier and is the ability of a ferroelectric material to withstand an external electric field without becoming depolarized. The coercive field thus may be an amount of energy required to depolarize a ferroelectric material and may be expressed in units of V/m or MV/cm, for example. The coercive field of the wurtzite material in its initial state may be approximately 6 MV/cm or more. The wurtzite material may be a wurtzite nitride material or a mixed wurtzite nitride material, for example but not limited to aluminum nitride, gallium nitride, indium nitride, boron-substituted aluminum nitride, scandium-substituted aluminum nitride, aluminum gallium nitride, and indium gallium aluminum nitride.

The method next includes irradiating the substrate with energetic particles to stabilize a defect chemistry in the crystalline structure of the wurtzite material. The defect chemistry may be, for example, a vacancy (missing atom), an interstitial (an atom in the wrong space/lattice position), or a substitution. The energetic particles generally have an energy that is in a range of from 0.1 keV to 3000 keV, optionally from 0.1 keV to 1000 keV, optionally from 0.1 keV to 500 keV, optionally from 0.1 keV to 300 keV, optionally from 0.1 keV to 100 keV, optionally from 0.1 keV to 50 keV, optionally from 0.1 keV to 40 keV, optionally from 0.1 keV to 30 keV, optionally from 0.1 keV to 25 keV, optionally from 0.1 keV to 20 keV, optionally from 0.1 keV to 10 keV, optionally from 1 keV to 3000 keV, optionally from 1 keV to 1000 keV, optionally from 1 keV to 500 keV, optionally from 1 keV to 300 keV, optionally from 1 keV to 100 keV, optionally from 1 keV to 50 keV, optionally from 1 keV to 40 keV, optionally from 1keV to 30 keV, optionally from 1 keV to 25 keV, optionally from 1 keV to 20 keV, optionally from 1 keV to 10 keV,. In certain embodiments, the energetic particles are positively-charged helium ions which are formed by removing an electron from each helium atom. The helium ions may have energies equal to or less than 30 keV. In other embodiments, the energetic particles may positively-charged inert ions formed by removing electrons from an inert gas such as nitrogen, neon, argon, krypton, xenon, and/or radon. In yet other embodiments, the energetic particles may be positively-charged reactive ions formed by removing electrons from a reactive gas such as oxygen. In yet other embodiments, the energetic particles may be positively-charged metal ions formed by removing electrons from metal atoms such as, for example, gallium, gold, or iridium. While the energetic particles are described by way of example as positively-charged ions, it should be understood that the energetic particles alternatively may include negatively-charged ions or charge-neutral materials. In various embodiments, the irradiation may be performed by energetic particle bombardment such as focused-beam ion irradiation, broad-beam ion irradiation, or plasma-based ion bombardment, for example but not limited to, Ga-FIB, PFIB, GFIS, kaufman ion source, particle accelerator-based ion irradiation, cyclotron accelerator irradiation, ion implanters, high-energy plasma ion sources, or nuclear reactor neutron sources.

The irradiated substrate has a lower switching energy barrier than the initial state of the crystalline structure of the wurtzite material. As such, the coercive field of the substrate is reduced due to one or more defect chemistries introduced by the irradiation. The coercive field may be reduced in an amount that is proportional to the amount or degree of the irradiation, such that as the amount of irradiation of the wurtzite material increases, the amount of reduction in the coercive field of the wurtzite material increases. In some embodiments, the coercive field is reduced in an amount that is greater than 0 and up to approximately 40% relative to the initial state of the wurtzite material. In alternative embodiments, the coercive field may be reduced in amount greater than 40%, such as up to 45%, optionally up to 50%, optionally up to 60%, optionally up to 70%, optionally up to 80%, optionally up to 90%, and in some embodiments the amount of reduction may be up to 100% or more. For example, the coercive field of the wurtzite material may be reduced from approximately 6 MV/cm to approximately 3 MV/cm, thereby greatly lowering the switching energy barrier of the wurtzite material which in turn reduces the amount of energy required to switch the polarization of the wurtzite material.

In certain embodiments, the method includes defining a pattern area on the substrate that corresponds to a portion or portions of the substrate that are desired to be irradiated with the energetic particles. The method also includes ionizing a source gas to produce positively-charged ions, and accelerating the positively-charged ions by applying an acceleration voltage and electrostatically focusing the accelerated ions into a nanometer-scale beam. The acceleration voltage may be in a range of, for example, 100 V to 50 kV. The source gas may be, for example, helium gas, oxygen gas, nitrogen gas, or an inert gas other than helium or nitrogen. The method next includes scanning the beam over the pattern area of the substrate to irradiate the pattern area with the positively-charged ions. The beam of positively-charged ions induce a modification of the crystalline microstructure and/or defect chemistry of the wurtzite material, thereby reducing the coercive field of the substrate. The method may include setting one or more parameters including but not limited to the ion dose (total number of energetic ions delivered to the pattern area), ion energy, ion flux, ion current (number of energetic ions delivered per unit time), dwell time, ion type/chemistry, ion charge state, ion source, incident angle of irradiation, substrate temperature, surface adsorbates, and ion pulsing.

In other certain embodiments, the method includes defining a pattern area on the substrate that corresponds to a portion or portions of the substrate that are desired to be irradiated with the energetic particles. The method also includes providing a source of energetic particles. The energetic particles may be, for example, inert gas ions, non-inert gas ions, or metallic ions. Further, the energetic particles may be positively-charged ions or negatively-charged ions. In alternative embodiments, the energetic particles may be charge neutral particles. The method next includes irradiating the pattern area of the substrate with the energetic particles. The energetic particles induce a modification of the crystalline microstructure and/or defect chemistry of the wurtzite material, thereby reducing the coercive field of the substrate.

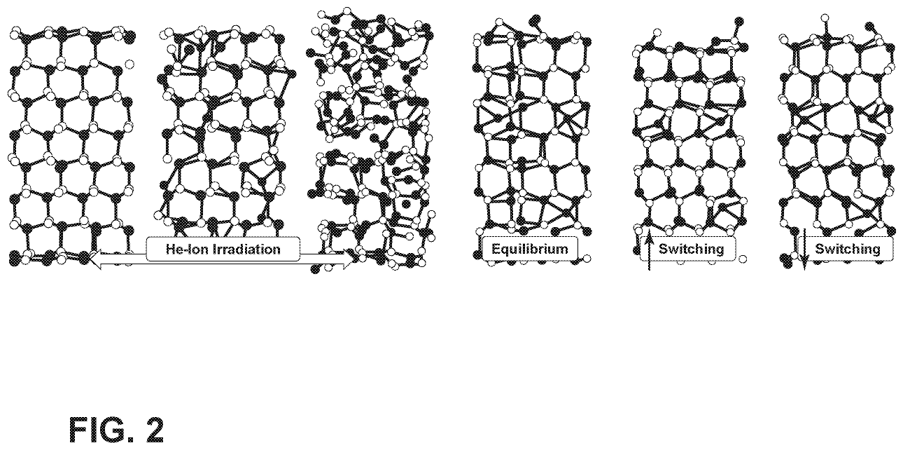

The defect chemistry introduced by the irradiation according to the embodiments of the method may enable localized domain nucleation, while subsequent domain growth proceeds by column-by-column switching along the polar axis. Reactive force field molecular dynamics simulations were conducted to irradiate a pristine aluminum nitride crystal with eight helium atoms (3.5 keV kinetic energy) to generate a damaged crystal, followed by equilibrating the system and applying a sinusoidal electric field to both pristine and damaged crystals to simulate polarization switching. Simulation snapshots related to the He-irradiation, equilibration, and polarization switching simulations are shown in FIG. 2. The left three views illustrate bombardment of the pristine crystal with the helium atoms. The resulting equilibrated crystal is shown in the middle-right view which includes a clearly visible line defect. The right two views illustrate that the Al—N—Al connection switches from puckered up to puckered down in response to a change in the direction of the electric field (±25 MV cm⁻¹), through which the applied electric filed partially reconfigures the irradiated crystal. The switching barrier is substantially reduced relative to pristine AlN, at about 48% lower for the irradiated crystal relative to the pristine AlN.

### EXAMPLES

The present method is further described in connection with the following laboratory examples, which are intended to be non-limiting.

Al₁₋ₓBₓN and AlN thin films were grown on Si substrates using a custom magnetron sputtering system having four 2-inch cathodes with Al, BN, and W targets. The magnetrons were disposed in a confocal configuration with a 22.5° attack angle with respect to the substrate normal. The Al and BN targets were powered by RF power supplies, while the W back electrodes were powered by a DC supply in DC mode. The Si substrates were heated radiantly using a modified substrate manipulator/heater stage. The untreated Si substrates were exposed with an RF 1:1N₂<:Ar plasma at 50 watts for 20 minutes at 350 °C. Next, while keeping the temperature at 350 °C, a 30 nm seed layer of AIN was grown to establish (0002) texture, followed by 100 nm of W-metal with (110) texture. The W was randomly oriented in-plane with a (110) rocking curve of approximately 1.7°. AlN and Al₁₋ₓBₓN films were prepared by co-sputtering from their respective targets at the same temperature.

A combination of electron beam lithography (EBL) and a metal lift off process were used to fabricate capacitor devices. The substrate was cleaned with acetone and IPA prior to spin-coating it with 950 PMMA A2 electron beam resist at 3000 rpm for 45 seconds, and baked on a hotplate for 2 minutes at 180 °C. Electron beam lithography was performed at 100 kV acceleration voltage. A 40 nA beam current and 1000 μC cm⁻² dose were used to define the geometry of the capacitors. The patterned substrate was developed in 1:3 methyl isobutyl ketone (MIBK): isopropyl alcohol (IPA) for 1 minute, rinsed with IPA, and dried with nitrogen, followed by exposure to oxygen plasma for 6 seconds at 100 W, 10 sccm O₂, and 150 mT. A lift-off process, using acetone and IPA, was carried out following deposition of 5 nm Ti and 20 nm Au by electron beam evaporation.

Prior to exposure, a 10 minute oxygen plasma clean was performed on the thin films to reduce helium ion induced carbon contamination. The following common parameters were used for all dosages: 25 keV acceleration voltage, 10 nm pixel spacing, 1 μs dwell time, and 119 pA beam current. Dosage was controlled with repeat raster passes over the irradiated region. The irradiation was performed using a helium ion microscope (HIM) operating at an acceleration voltage of 25 keV. A beam current of 142 pA was achieved using a spot size setting of 4.29 and the big hole aperture. The dwell time was set to 1 μs per pixel, with a pixel spacing (pitch) of 10 nm.

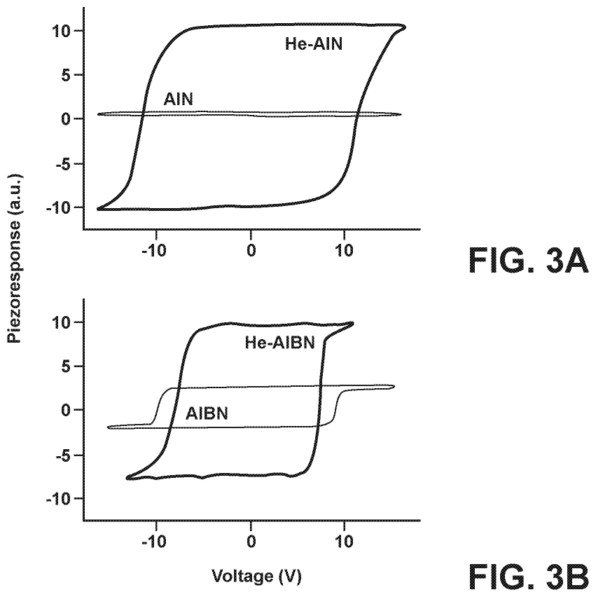

The as-grown AIN did not display ferroelectricity at room temperature. Upon helium-ion irradiation at a dose of approximately 1000 ions nm⁻², an induced concentration of defects activated AlN's ferroelectric response. With greater irradiation dose, the film exhibited both accelerated switching kinetics and a marked increase in switched polarization, consistent with a larger switched volume and a higher density of active nucleation sites. Kolmogorov-Avrami-Ishibashi analysis of switching dynamics yielded Avrami exponents (n≈1) at both 500 and 1000 ions nm⁻², identifying a nucleation-limited switching regime dominated by percolative nucleation with negligible domain-wall propagation. This mechanism contrasted sharply with scandium-or boron-alloyed AlN (n≈1.7), which shows evidence of both nucleation and significant domain growth. In band-excitation piezoresponse spectroscopy (BEPS) indicated that the defects induced by ion irradiation were capable of activating ferroelectricity in AlN and reducing coercive voltage in Al_{0.92}B_{0.08}N as shown in FIGS. 3A and 3B. Domain inversion in the ferroelectric region fabricated through irradiation-based direct writing was thus evidenced by a reversal in phase after applying −20 V. Accordingly, the coercive field mapping revealed a relatively homogeneous coercive voltage across the irradiated region, while the pristine area remained piezoelectric with no observed polarization reversal.

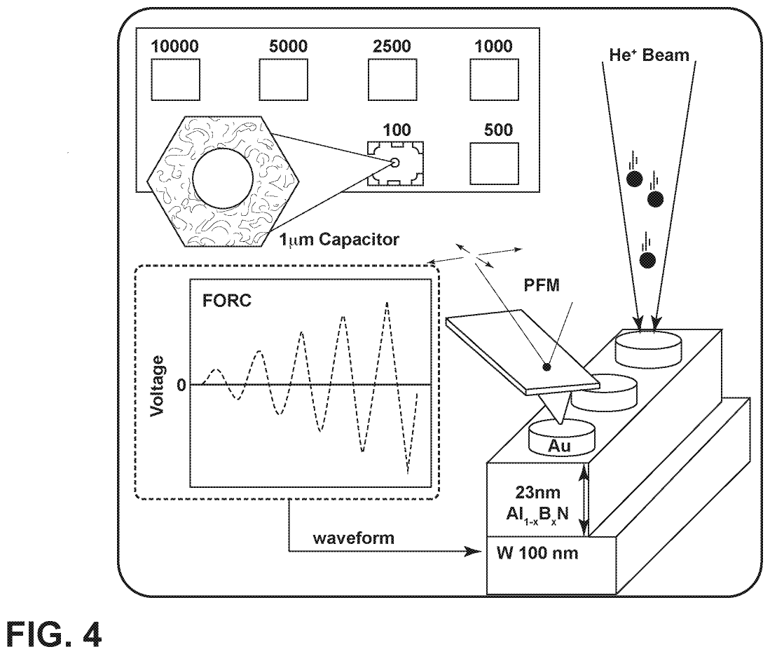

The Al_{0.92}B_{0.08}N capacitors were also irradiated with helium ions. The helium ion collisions cumulatively increased defect concentrations as the irradiation dose increased (time-integrated count of helium ions incident per unit area). As shown in FIG. 4, lithographically fabricated 1 μm diameter capacitors on a 23 nm Al_{0.92}B_{0.08}N film were subjected to helium ion doses spanning several orders of magnitude up to 10000 ions nm⁻² to illustrate that higher defect concentrations correspond to reduced energy barriers for ferroelectric switching. Band-excitation piezoresponse force microscopy was employed to probe the local electromechanical coupling of ion-irradiated regions and to conduct voltage spectroscopy.

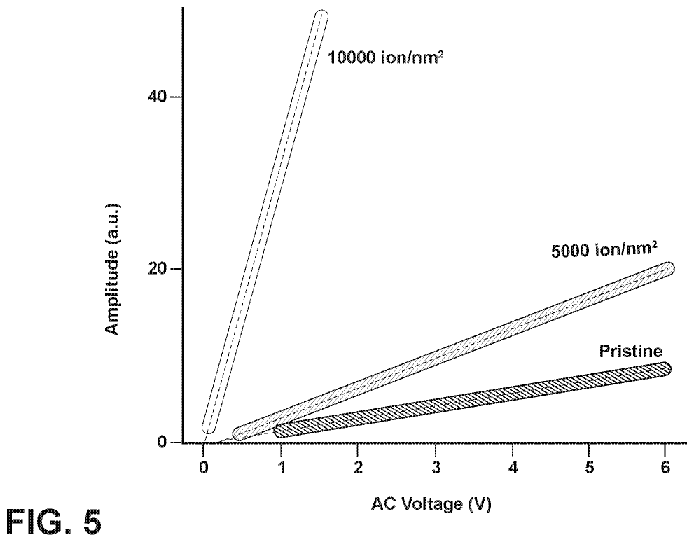

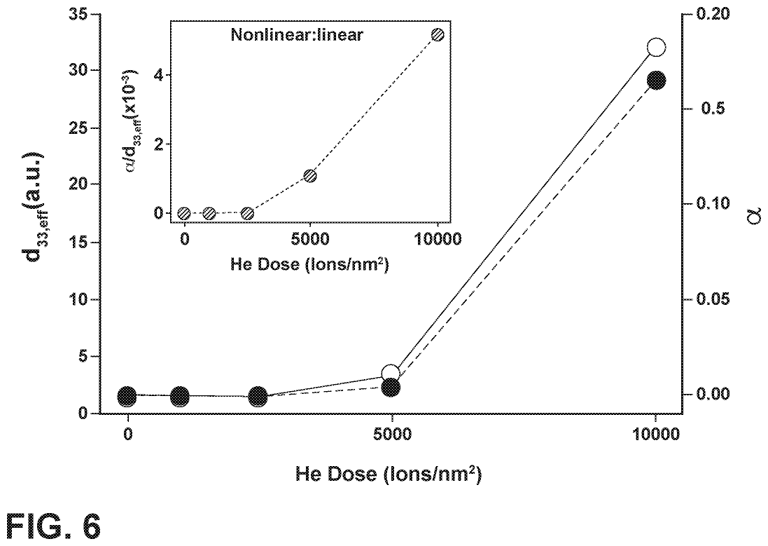

Electromechanical coupling was measured by applying a variable amplitude AC signal through an AFM probe atop the capacitor. As shown in FIG. 5, ion irradiation induced an apparent 10× enhancement in electromechanical response. As shown in FIG. 6, the piezoresponse force microscopy (PFM) amplitude-VAC curves were fit to a second-order polynomial in which the linear term coefficient corresponds to the effective piezoelectric coefficient (d33, eff) and the quadratic term coefficient (α) captures nonlinearity from processes such as domain-wall motion (bowing/depinning), defect interactions, and dissipative contributions. The corresponding fitted coefficients, d33, eff and α, increase with irradiation dose. The results point to an extrinsic, defect-assisted mechanism for irradiation-induced electromechanical enhancement.

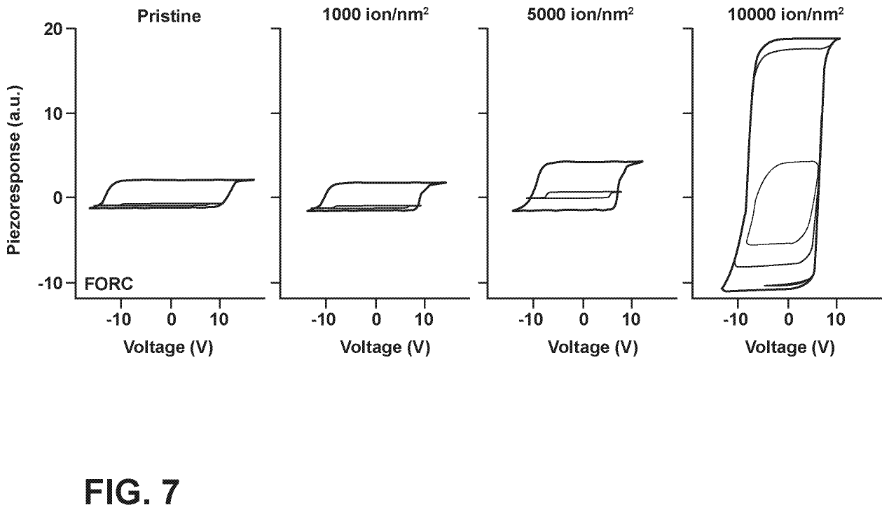

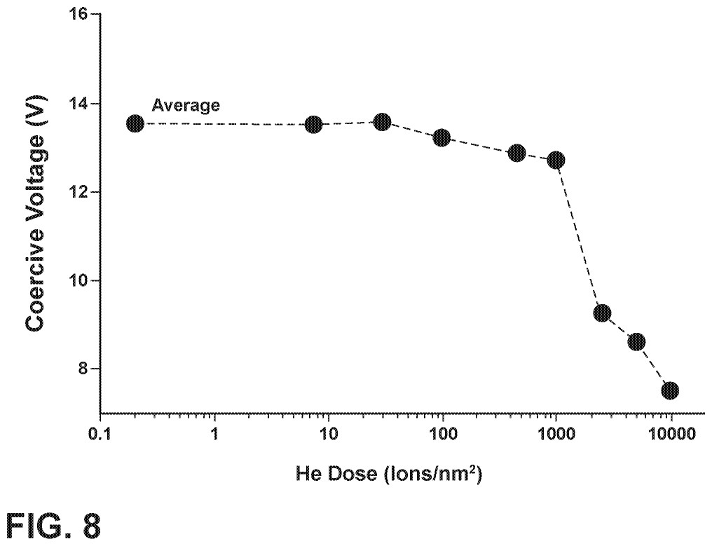

The defect-mediated switching pathway imposed by helium irradiation in Al_{0.92}B_{0.08}N achieves a 41% reduction in coercive voltage at the highest ion dose used, overcoming the intrinsic limitations posed by boron substitution, which in contrast plateaus at boron's solubility limit with only a 13% decrease in coercive field from the onset of ferroelectricity. As shown in FIGS. 7 and 8, the coercive field reduction with increasing dose is initially gradual, then steeply reduces at a critical exposure dose. At higher doses, ferroelectric wake-up broadens the distribution of switching fields, indicative of partial switching, and the corresponding PFM phase measurements confirm that the films initialize from the same polarization state.

The above description is that of current embodiments of the invention. Various alterations and changes can be made without departing from the spirit and broader aspects of the invention as defined in the appended claims, which are to be interpreted in accordance with the principles of patent law including the doctrine of equivalents. This disclosure is presented for illustrative purposes and should not be interpreted as an exhaustive description of all embodiments of the invention or to limit the scope of the claims to the specific elements illustrated or described in connection with these embodiments. For example, and without limitation, any individual element(s) of the described invention may be replaced by alternative elements that provide substantially similar functionality or otherwise provide adequate operation. This includes, for example, presently known alternative elements, such as those that might be currently known to one skilled in the art, and alternative elements that may be developed in the future, such as those that one skilled in the art might, upon development, recognize as an alternative. Further, the disclosed embodiments include a plurality of features that are described in concert and that might cooperatively provide a collection of benefits. The present invention is not limited to only those embodiments that include all of these features or that provide all of the stated benefits, except to the extent otherwise expressly set forth in the issued claims. Any reference to claim elements in the singular, for example, using the articles “a,” “an,” “the” or “said,” is not to be construed as limiting the element to the singular.

What is claimed is:

1. A method of inducing kinetic transformations in the defect chemistry of a wurtzite material, the method comprising:
providing a substrate comprised of a wurtzite material having a crystalline structure in an initial state and defining a ferroelectric coercive field;
irradiating the substrate with energetic particles to stabilize a defect chemistry in the crystalline structure of the wurtzite material, wherein the irradiated substrate has a lower switching energy barrier than the initial state of the crystalline structure of the wurtzite material;
whereby the coercive field of the substrate is reduced.

2. The method of claim 1, wherein the energetic particles are ions with an energy that is in a range of from 0.1 keV to 3000 keV.

3. The method of claim 1, wherein the energetic particles are helium ions.

4. The method of claim 3, wherein the energetic particles have an energy that is equal to or less than approximately 30 keV.

5. The method of claim 1, wherein the energetic particles are inert ions.

6. The method of claim 1, wherein the energetic particles are reactive ions.

7. The method of claim 1, wherein the energetic particles are metal ions.

8. The method of claim 1, wherein the wurtzite material is a wurtzite nitride material or a mixed wurtzite nitride material.

9. The method of claim 8, wherein the wurtzite material is one of aluminum nitride, gallium nitride, indium nitride, boron-substituted aluminum nitride, scandium-substituted aluminum nitride, aluminum gallium nitride, and indium gallium aluminum nitride.

10. The method of claim 1, wherein the coercive field is reduced in an amount proportional to an amount of the irradiation.

11. The method of claim 10, wherein the coercive field is reduced in a range of from greater than 0 to up to 40%.

12. The method of claim 1, wherein the irradiation is performed by energetic particle bombardment that is one of focused-beam ion irradiation, broad-beam ion irradiation, and plasma-based ion bombardment.

13. A method of inducing kinetic transformations in the defect chemistry of a wurtzite material by energetic particle irradiation, the method comprising:
providing a substrate comprised of a wurtzite material having a spontaneous polarization and a ferroelectric coercive field;
defining a pattern area on the substrate;
ionizing a source gas to produce positively-charged ions;
accelerating the positively-charged ions by applying an acceleration voltage and electrostatically focusing the accelerated ions into a nanometer-scale beam;
scanning the beam over the pattern area of the substrate;
wherein the beam induces a modification of crystalline microstructure and/or defect chemistry of the wurtzite material, thereby reducing the coercive field of the substrate.

14. The method of claim 13, wherein the accelerated ions have an energy that is in a range of from 0.1 keV to 3000 keV.

15. The method of claim 13, wherein the source gas comprises at least one of helium gas, oxygen gas, nitrogen gas, or an inert gas.

16. The method of claim 13, wherein the wurtzite material is a wurtzite nitride material or a mixed wurtzite nitride material.

17. A method of inducing kinetic transformations in the defect chemistry of a wurtzite material by energetic particle irradiation, the method comprising:
providing a substrate comprised of a wurtzite material having a spontaneous polarization and a ferroelectric coercive field;
defining a pattern area on the substrate;
providing a source of energetic particles;
irradiating the pattern area of the substrate with the energetic particles;
wherein the energetic particles induce a modification of crystalline microstructure and/or defect chemistry of the wurtzite material, thereby reducing the coercive field of the substrate.

18. The method of claim 17, wherein the energetic particles have an energy that is in a range of from 0.5 keV to 3000 keV.

19. The method of claim 17, wherein the energetic particles are one of inert gas ions, non-inert gas ions, and metallic ions.

20. The method of claim 17, wherein the energetic particles are one of positively-charged ions, negatively-charged ions, or charge neutral particles.

21. The method of claim 17, wherein the wurtzite material is a wurtzite nitride material or a mixed wurtzite nitride material.
